(19) United States
(12) Patent Application Publication
(10) Pub. No.: US 2025/0038482 A1
(43) Pub. Date: Jan. 30, 2025

(54) SEMICONDUCTOR COMPONENT

(71) Applicant: TRUMPF Photonic Components GmbH, Ulm (DE)

(72) Inventors: Stephan GRONENBORN, Aachen (DE); Johanna Sophie KOLB, Aachen (DE)

(21) Appl. No.: 18/916,771

(22) Filed: Oct. 16, 2024

Related U.S. Application Data
(63) Continuation of application No. PCT/EP2023/060021, filed on Apr. 18, 2023.

(30) Foreign Application Priority Data
Apr. 19, 2022 (DE) 10 2022 109 448.0

(51) Int. Cl. H01S 5/22; H01S 5/042

(52) U.S. Cl. CPC H01S 5/22; H01S 5/0421

(57) ABSTRACT

A semiconductor component for emitting light includes a main body having at least one mesa unit. The mesa unit has at least one mesa portion with an emission region arranged on a surface of the main body. The emission region includes a first mirror portion, a second mirror portion, and an active layer arranged between the first mirror portion and the second mirror portion for generating the light. The semiconductor component further includes at least one contact unit for feeding electrical energy into the active layer. The contact unit has a joining portion for externally contacting the semiconductor component, and an active contact portion extending from the joining portion to the mesa portion. The active contact portion is arranged only on one longitudinal side of the mesa unit, so that the mesa unit is not completely surrounded by the active contact portion along the surface.

### CROSS REFERENCE TO RELATED APPLICATIONS

This application is a continuation of International Application No. PCT/EP2023/060021 (WO 2023/203026 A1), filed on Apr. 18, 2023, and claims benefit to German Patent Application No. DE 10 2022 109 448.0, filed on Apr. 19, 2022. The aforementioned applications are hereby incorporated by reference herein.

### FIELD

Embodiments of the present invention relate to a semiconductor component for emitting laser light.

### SUMMARY

Embodiments of the present invention provide a semiconductor component for emitting light. The semiconductor component includes a main body having at least one mesa unit. The mesa unit has at least one mesa portion with an emission region arranged on a surface of the main body. The emission region includes a first mirror portion, a second mirror portion, and an active layer arranged between the first mirror portion and the second mirror portion for generating the light. The semiconductor component further includes at least one contact unit for feeding electrical energy into the active layer. The contact unit has a joining portion for externally contacting the semiconductor component, and an active contact portion extending from the joining portion to the mesa portion. The active contact portion is arranged only on one longitudinal side of the mesa unit, so that the mesa unit is not completely surrounded by the active contact portion along the surface.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a plan view of a semiconductor device with mesa units according to some embodiments.

### DETAILED DESCRIPTION

Embodiments of the present invention provide a semiconductor component for emitting light, which has a main body that has at least one mesa unit that has at least one mesa portion with an emission region for the light arranged on a surface of the main body, to which are assigned a first mirror portion, a second mirror portion, and an active layer arranged between the two mirror portions for generating the light, wherein the semiconductor component has at least one contact unit for feeding electrical energy into the active layer, wherein the contact unit has a joining portion provided for externally contacting the semiconductor component and an active contact portion extending from the joining portion to the mesa portion, wherein the active contact portion is arranged only on one mesa side of the mesa unit, so that the mesa unit is not completely surrounded by the active contact portion along the surface.

This allows a larger proportion of the surface to be covered with electrical contacts compared to conventional designs, so that a fill factor based on the area covered and uncovered by electrical contacts is advantageous.

Such an advantageous semiconductor component can be used in exemplary applications such as smartphones or data glasses to realize, for example, augment reality, 3D camera, and/or triangulation functions.

For this purpose, a large number of point or line patterns generated by the mesa units can be achieved through the improved fill factor. The distance between the emission regions can thus be reduced.

Furthermore, separately addressable groups of mesa units can be densely packed on the surface so that a number of mesa units, mesa portions and/or emission regions per unit area is larger than in conventional, in particular array-type semiconductor components.

However, the close arrangement of the mesa units, mesa portions, and/or emission regions can lead to small distances between the active contact portions. To prevent unwanted current flows between active contact portions, a minimum distance between the active contact portions is necessary. To nevertheless enable an active contact portion that is sufficiently wide with regard to electrical properties, the active contact portions are arranged according to embodiments of the invention.

Preferably, it can be provided that the mesa unit is shaped in a straight line, wherein the active contact portion is arranged along a longitudinal side with respect to a longitudinal axis of the mesa unit. Accordingly, the elongated mesa unit has an active contact portion only on one longitudinal side. This enables a closer arrangement of the mesa units, in contrast to a conventional arrangement in which the active contact portions of the mesa portions completely surround the mesa units.

In particular, the active contact portion is formed along at least the entire longitudinal side of a rectilinear mesa portion. This ensures that the active layer of a mesa portion can be completely and evenly supplied with electrical energy.

Advantageously, the mesa unit has at least one rectilinear emission region along which the active contact portion is arranged. This ensures that the active layer below the emission region is reliably supplied with electrical energy.

In particular, the longitudinal ends of the emission regions are surrounded by offset portions of the active contact portions. In this case, extensions of the active contact portion extend from the longitudinal side to the longitudinal ends of the respective emission region so that the portions of the active layer below the longitudinal ends are also supplied with electrical energy.

It can be provided that the main body has at least one point emission region.

In an development, it can be provided that several emission regions of a mesa unit are arranged along a straight row axis. The emission regions can be point-shaped and/or elongated. Furthermore, the emission regions can be arranged on a mesa portion or individual emission regions can each be arranged on a mesa portion.

Preferably, a mesa unit has mutually discrete mesa portions arranged along the longitudinal axis. The mesa portions are separated from each other by separating trenches, for example. This allows a linear array of mesa portions to be created within a mesa unit.

To achieve an advantageous fill factor, a portion edge of the active contact portion can be formed to be parallel to the longitudinal axis of the mesa unit associated with the active contact portion. The longitudinal axis preferably runs centrally through the mesa units, emission regions and/or mesa portions.

Advantageously, the main body can have several mesa units, wherein the longitudinal axes of the mesa units are aligned to be parallel to each other. This makes it possible to realize an array of mesa units on the main body, in which the different mesa units extend along an array axis perpendicular to the longitudinal axis of the respective mesa units.

It can be advantageous for linear emission regions to be of different lengths. A variation of the design of the emission regions is possible depending on the application of the semiconductor component.

A high degree of adaptation to the application of the semiconductor device can be achieved by assigning the emission regions of different lengths to different mesa units.

It is preferred that the active contact portions of different mesa units are arranged on the same longitudinal side. It is to be understood that the features specified above and the features yet to be explained below can be used not only in the specified combination but also in other combinations.

Each embodiment of the present invention can be configured as what is termed a top emitter and/or bottom emitter.

Embodiments of the present invention are explained in more detail below with reference to the associated drawings. Direction indications in the following explanation are to be understood according to the reading direction of the drawings.

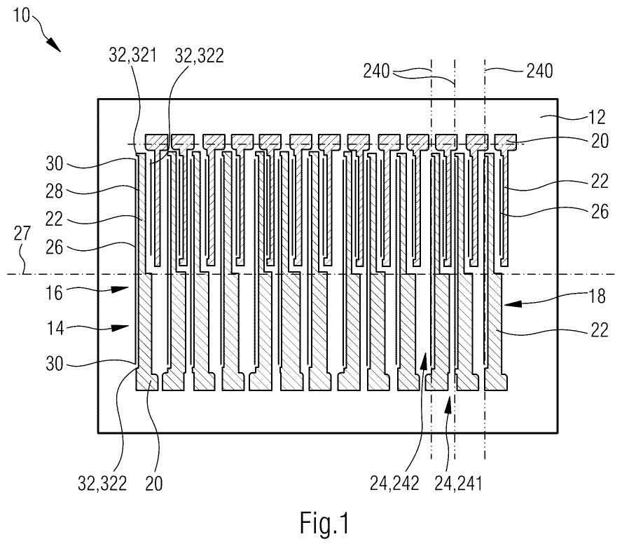

FIG. 1 shows a semiconductor component 10 for emitting light, which has a main body 12 having at least one mesa unit 14 having at least one mesa portion 16 with an emission region 26 for the light arranged on a surface of the main body 12.

The mesa portion 16 comprises at least partially a first mirror portion, a second mirror portion, and an active layer arranged between the two mirror portions for generating the light. At least the mesa portion 16 is constructed from stacked functional layers and are.

At least one contact unit 18 for feeding electrical energy into the active layer is arranged on a surface of the main body 12, wherein the contact unit 18 has a joining portion 20 provided for externally contacting the semiconductor component 10 and an active contact portion 22 extending from the joining portion 20 to the mesa portion 16.

The joining portion 20 can be connected to electrical supply lines by means of a wire bonding process or a soldering process.

The active contact portion 22 is preferably strip-shaped and arranged only on one mesa side 241 of the mesa unit 14. The mesa unit 14 is not completely surrounded by the active contact portion 22 along the surface. At least a second mesa side 242, which is opposite a first mesa side 241 of the mesa unit 14 provided with the active contact portion 22, does not have an active contact portion 22.

Purely by way of example, the mesa unit 14 can be shaped in a straight line, with the active contact portion 22 being arranged along the first mesa side 241, which represents the longitudinal side 24 with respect to a longitudinal axis 240 of the mesa unit 14. The longitudinal axis 240 is preferably arranged centrally through the mesa unit 14, emission regions 26, and/or mesa portions 16.

If the mesa unit 14 has an elongated mesa portion 16 that is formed in a straight line along the surface, then the active contact portion 22 can be formed along the entire longitudinal side 24 of the mesa portion 16. The elongated mesa portion 16 also gives the mesa unit 14 an elongated structure. In particular, this is also the case with rectilinear emission regions 26, wherein the active contact portion 22 is arranged on a longitudinal side 24 of the strip-shaped emission region 26.

By forming the active contact portion along the entire longitudinal side 24 of the mesa unit 14, the mesa portion 16 and/or the emission region 26, the active layer below the emission region 26 can be supplied with electrical energy. This achieves a uniform emission intensity along the entire emission region 26.

Furthermore, the longitudinal ends 30 of the emission regions 26 can be surrounded by offset portions 32 of the active contact portions. The offset portions 32 of the active contact portions can be formed as extensions that extend substantially transversely to the longitudinal axis 240. A first offset portion 321 can be arranged at a free end of an active contact portion 22 and a second offset portion 322 can be arranged between the joining portion 20 and the active contact portion 22. By implementing offset portions 32, the active contact portion 22 is longer than the emission region 26. As a result, the portions of the active layer below the longitudinal ends 30 will also be supplied with electrical energy. The offset portions 32 do not extend to the second mesa side 242.

A portion edge 28 of the active contact portion 22 of a mesa unit 14 facing the emission region 26 is parallel to the longitudinal axis 240 assigned to the mesa unit 14.

A semiconductor device 10 can be formed as an array with a plurality of mesa units 14. The main body 12 has several mesa units 14, the longitudinal axes 240 of which are aligned to be parallel to each other. The different mesa units 14 are arranged adjacent to each other and form an array, the array direction of which is perpendicular to the longitudinal axis 240 of the respective mesa units 14.

The linear emission regions 26 of the different mesa units 14 are of different lengths in the exemplary embodiment of FIG. 1. The emission regions 26 of neighboring mesa units 14 are of different lengths. First emission regions 26 and second emission regions 26 can be provided which are of different lengths compared to one another. In this case, the same number of first and second emission regions 26 are provided in the semiconductor component 10. Preferably, the first and second emission regions 26 alternate periodically along the array direction of the array.

The joining portions 20 of the first emission regions 26 are preferably arranged on a first longitudinal side of the array axis 27 and the joining portions 20 of the second emission regions 26 are preferably arranged on a second longitudinal side of the array axis 27.

Preferably, the individual active contact portions 22 can be supplied with electrical voltage independently of one another, so that the mesa portions 16 supplied by the respective active contact portions 22 can be separately excited to emit laser light.

Regardless of the shape of the emission regions 26, the mesa units 14, and/or the mesa portions 16, the active contact portions 22 are arranged on the same longitudinal side of the longitudinal axes 240.

For example, the active contact portions 22 of long first mesa units 14 according to FIG. 1 can be arranged on the first mesa side 241, wherein the active contact portion extends over the entire length of the emission region 26. At the regions of the longitudinal ends 30 of the emission regions 26, the protruding portions 32 of the active contact portions 22 extend in the direction of the second mesa sides 242. The joining portions 20 are arranged on a common side with respect to the array axis 27. The joining portions 20 of the second mesa units 242 are on the opposite side with respect to the array axis 27. The shorter second mesa units 14 are arranged at the same locations with respect to the longitudinal axes 240. The first longitudinal ends 321 of the emission regions 26 of the first mesa units 14 are at the same height as the second longitudinal ends 322 of the emission regions 26 of the second mesa units 14, so that the array arrangement is not symmetrical with respect to the array axis 27. The array axis 27 can run approximately centrally along the array arrangement. Along the longitudinal axes of the first mesa units 14, the width of the active contact portion 22 parallel to the array axis 27 is smaller in the region of the second mesa unit 14 than in regions without a mesa unit 14.

Another exemplary embodiment can include the main body 12 having a plurality of emission regions 26 of a mesa unit 14 arranged along a straight row axis. The row axis can be the longitudinal axis 240. The emission regions 26 can be point-shaped and/or elongated. Furthermore, the emission regions 26 can be arranged on a mesa portion 16 or individual emission regions 26 can each be arranged on a separate mesa portion 16.

Preferably, a mesa unit 14 has mutually discrete mesa portions 16 which are arranged along the longitudinal axis 240. The mesa portions 16 are separated from each other, for example, by separating trenches. This allows a linear array of mesa portions 16 to be produced within a mesa unit 14.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SYMBOLS

10 Semiconductor component
12 Main body
14 Mesa unit
16 Mesa portion
18 Contact unit
20 Joining portion
22 Active contact portion
24 Longitudinal side
240 Longitudinal axis
241 First mesa side
242 Second mesa side
26 Emission region
27 Array axis
28 Portion edge
30 Longitudinal end
32 Offset portion
321 First offset portion
322 Second offset portion

1. A semiconductor component for emitting light comprising:
a main body having at least one mesa unit, which has at least one mesa portion with an emission region arranged on a surface of the main body, wherein the emission region comprises a first mirror portion, a second mirror portion, and an active layer arranged between the first mirror portion and the second mirror portion for generating the light, and
at least one contact unit for feeding electrical energy into the active layer, the contact unit having a joining portion for externally contacting the semiconductor component and an active contact portion extending from the joining portion to the mesa portion, the active contact portion being arranged only on one longitudinal side of the mesa unit so that the mesa unit is not completely surrounded by the active contact portion along the surface.

2. The semiconductor component according to claim 1, wherein the mesa unit is formed as being rectilinear, wherein the active contact portion is arranged along the one longitudinal side with respect to a longitudinal axis of the mesa unit.

3. The semiconductor component according to claim 1, wherein the active contact portion is formed along an entirety of the one longitudinal side of the mesa unit.

4. The semiconductor component according to claim 1, wherein the mesa unit has at least one rectilinear emission region, and wherein the active contact portion is arranged along the rectilinear emission region.

5. The semiconductor component according to claim 4, wherein longitudinal ends of the rectilinear emission region are surrounded by offset portions of the active contact portion.

6. The semiconductor component according to claim 1, wherein the main body has at least one point emission region.

7. The semiconductor component according to claim 1, wherein a plurality of emission regions of the mesa unit is arranged along a straight row axis.

8. The semiconductor component according to claim 7, wherein the plurality of emission regions is formed on the mesa portion.

9. The semiconductor component according to claim 1, wherein the mesa unit has a plurality of mutually discrete mesa portions arranged along a longitudinal axis.

10. The semiconductor component according to claim 1, wherein a portion edge of the active contact portion is formed to be parallel to a longitudinal axis of the mesa unit associated with the active contact portion.

11. The semiconductor component according to claim 2, wherein the main body has a plurality of mesa units, wherein the longitudinal axes of the mesa units are aligned to be parallel to one another.

12. The semiconductor component according to claim 4, comprising a plurality of rectilinear emission regions of different lengths.

13. The semiconductor component according to claim 12, comprising a plurality of mesa units, wherein the rectilinear emission regions of different lengths are assigned to different mesa units.

14. The semiconductor component according to claim 12, wherein the active contact portions of the different mesa units are arranged on the same longitudinal side.
